(19) United States
(12) Patent Application Publication
(10) Pub. No.: US 2015/0021549 A1
(43) Pub. Date: Jan. 22, 2015

(54) LIGHT EMITTING DIODES WITH QUANTUM DOT PHOSPHORS

(71) Applicant: The Penn State Research Foundation, University Park, PA (US)

(72) Inventors: Fan Zhang, State College, PA (US); Jian Xu, State College, PA (US); Suzanne Mohney, State College, PA (US)

(21) Appl. No.: 14/487,783

(22) Filed: Sep. 16, 2014

Related U.S. Application Data
(63) Continuation-in-part of application No. 13/744,526, filed on Jan. 18, 2013, now Pat. No. 8,835,965.
(60) Provisional application No. 61/587,884, filed on Jan. 18, 2012.

(51) Int. Cl. H01L 33/00; H01L 33/12; H01L 33/40; H01L 33/50; H01L 33/06; H01L 33/34

(52) U.S. Cl. CPC H01L 33/0012; H01L 33/06; H01L 33/34; H01L 33/343; H01L 33/40; H01L 33/502; H01L 33/12
USPC 257/13

(57) ABSTRACT

A quantum well-based p-i-n light emitting diode is provided that includes nanopillars with an average linear dimension of between 50 nanometers and 1 micron. The nanopillars include a laminar layer of quantum wells capable of non-radiative energy transfer to quantum dot nanocrystals. Quantum dot-Quantum well coupling through the side walls of the nanopillar-configured LED structure achieves a close proximity between quantum wells and quantum dots while retaining the overlying contact electrode structures. An white LED with attractive properties relative to conventional incandescent and fluorescence lighting devices is produced.

### CROSS REFERENCE TO RELATED APPLICATIONS

This application is a continuation-in-part claiming priority benefit of the co-pending U.S. application Ser. No. 13/744,526 filed 18 Jan. 2013 which claims the priority benefit of U.S. Provisional Application Ser. No. 61/587,884 filed 18 Jan. 2012; the contents of each are hereby incorporated by reference.

### FIELD OF THE INVENTION

The present invention relates in general to a light emitting diode (LED) and in particular to a white light LED based on semiconductor quantum dots (QDs) used as phosphors.

### BACKGROUND OF THE INVENTION

White light emitting diode (LED) based solid-state lighting is commanding much attention worldwide for its promise of energy savings compared to incandescent and even compact fluorescent lighting. The energy efficiency, longevity, and material usage in manufacture are all attributes that favor white LED technology, yet technical problems persist. The predominant white LED technology involves the employment of high quantum efficiency (η≧60%) blue InGaN quantum well (QW) LEDs and the down conversion of blue radiation to yellow/green and red for white light generation. Y₃Al₅O₁₂:Ce³⁺ and Eu²⁺ doped nitridosilicates have been coated onto the InGaN QW LED as yellow/green and red phosphors such that trichromatic “cold white light” is produced by mixing red, yellow, green, and blue emission in the LED output.

There are, nevertheless, a number of limits on the performance of those white LEDs due to the phosphor conversion scheme employed. Since the existing red, yellow, and green phosphors have different chemical compositions, it is difficult to control the granule size and to mix and deposit uniform multi-phosphor films. Also, the different aging behavior of the multiple phosphor species often makes the device performance unstable in terms of the overall wavelength output. Current white LED lamps also manifest this phosphor aging differential as a shorter than desirable lamp operation lifetime. A more fundamental limit on the efficiency of the phosphor conversion white LEDs, however, lies in the multi-step “down conversion” scheme: high energy, blue photons produced by InGaN QW LEDs have to be absorbed by the phosphors first, and then, via impurity-level assisted transitions, are converted to low energy, long wavelength photons with a one-to-one correspondence. This process loses a significant portion of the photon energy to lattice vibrations (heat) in the phosphor media as a non-radiative conversion and is also limited by electron system crossings between singlet and triplet quantum states. The energy loss in the down-conversion process will, by itself, set the ultimate quantum efficiency of white LEDs below 65%.

Colloidal compound quantum dots (QDs) have been introduced to the white LED technology as a new family of phosphor materials with many superior properties. Due to strong quantum confinement, semiconductor QDs, such as core/shell CdSe/(Zn,Cd)S QDs, are characterized by sharp exciton absorption spectral features, extremely high luminescence efficiency (˜90-95%), and size tunable emission color spanning the entire visible spectrum. QDs of the same chemical composition and different size can therefore be employed to provide multiple spectral components in white LED output, with improved color quality and aging performance. The most significant potential of QD phosphors lies in the recent discovery that there exists a path for indirect injection of electron hole pairs into QDs (for radiative recombination and thus band edge emission from QDs) by noncontact, nonradiative energy transfer from a proximal InGaN quantum well (QW). The direct, non-radiative energy transfer path is considered to be the consequence of dipole-dipole interactions associated with QW-QD coupling and the extremely fast intraband relaxation in colloidal QDs (subpicosecond time scales). As indirect injection of electron hole pairs is fundamentally different from the traditional multi-step “down conversion” fluorescence scheme described previously and operative in traditional phosphors and removes several of the intermediate steps involved in color conversion, this approach has the prospect of eliminating energy losses associated with the steps and increasing the fundamental limit of efficiency.

As promising as the indirect injection of electron hole pairs into QD approach appears to be, it has to-date met with limit success. In one report, Chen et al. has demonstrated white LEDs by housing an InGaN blue LED chip in a silicon resin doped with green and red emitting CdSe/CdS. Since the QDs were physically separated from the emissive QWs in the LED chip, no QW-QD coupling was possible. A low efficiency of 7.2 lm/W was recorded.

In another study, Achermann et al. observed high efficiency color conversion in an electrically pumped light emitting diode (LED) using non-radiative energy transfer between an InGaN/GaN QW and a monolayer of CdSe/ZnS QDs. Spectroscopic measurements revealed that 13% of the radiative power of the QW was transferred almost loss free to red emission from the QDs when the QW and QDs were located in close proximity to each other. The viability of this work was limited in producing an actual LED device owing to the difficulty in resolving the inherent conflict between the need for close proximity of the QW and QDs and also the need for a sufficiently thick electrical contact layer with a low resistance for LED operation. In addition, the energy fraction (13%) channeled between the QW and QDs is still too low for viable device formation to leverage the benefits of white LEDS relative to conventional lighting devices. These experimental devices with weak QD phosphor emission compared to the bright blue radiation from the InGaN QW remain impractical for usage. Others have also widely investigated the application of QD phosphors, however all previous studies are focused on the energy coupling between QDs and direct band-gap semiconductors, such as InGaN and GaN.

Thus, there exists a need for quantum dots with varied emission colors coupled to an LED emitter that promotes efficient nonradiative energy transfer therebetween to achieve a practical white LED with low energy consumption. These also exists a need for a QW-QD white LED that is compatible with the presence of a bulk electrical contact layer. Finally there exists a need for a SiC diode that further promotes efficient nonradiative energy transfer.

### SUMMARY OF THE INVENTION

A light emitting diode is provided that includes a substrate, an anode having at least one anode contact said anode directly or indirectly layered on said substrate, a hole injection p-type layer directly or indirectly layered on said anode, an array of holes etched in said p-type layer infiltrated with a plurality of quantum dot phosphors, an electron transport n-type layer directly or indirectly layered on said hole injection layer forming a p-n homojunction therebetween, and a cathode having at least one cathode contact, said cathode directly or indirectly layered on said electron transport layer.

Coupling of the quantum dot phosphors to the side walls of the etched holes is employed to achieve efficient non-radiative transfer while retaining the overlying contact electrode structures with dimensions adjustable to desired thicknesses for improved efficiency. The quantum dot phosphors are accumulated into the etched holes of the p-type layer by soaking the p-type layer in a toluene solution of quantum dot phosphors.

### BRIEF DESCRIPTION OF THE DRAWINGS

The present invention is further detailed with reference to the following figures. These figures are not intended to be a limitation on the scope of the invention, but rather to illustrate specific aspects of the invention.

FIG. 1A shows a schematic of a SiC diode.

FIG. 1B provides a top view of an inventive SiC diode.

FIG. 2 is the electroluminescence spectra of the SiC diode with and without coupled QDs.

FIG. 3A is a plot of the absorption spectrum of the QD thin film.

FIG. 3B provides the excitation and photoluminescence spectra of the QD thin film.

FIG. 4A illustrates the steady-state photoluminescence of the SiC diode without QDs.

FIG. 4B provides a time-resolved photoluminescence of the SiC diode (392 nm) with and without QDs coating; and

FIG. 5 shows a schematic of an embodiment of an LED.

### DETAILED DESCRIPTION OF THE INVENTION

The present invention has utility as an LED with superior performance relative to conventional LEDs. The present invention achieves superior performance through minimizing the separation distance between the etched holes and visible-light emissive quantum dot phosphors. Coupling of the quantum dot phosphors through the side walls of the holes in the LED structure is employed to satisfy the requirements that were previously incompatible. Additionally, the present invention controls the geometric dimensions of the nanopillars as well as their separation distance to eliminate the total internal reflection for the enhanced light extraction efficiency. As the spectra emission from a quantum dot phosphor is a both a size-dependent and composition-dependent property, the overall spectral emission from an LED is controlled in certain embodiments of the present invention to include quantum dot phosphors that have different spectral emission to produce LEDs with controlled and desirable colors. The collective quantum dot band gaps are such that an emission discerned by a normal human eye as white in color is provided in certain inventive embodiments.

According to the present invention, a substrate supports an n-type doped semiconductor layer overlaid with a p-type doped semiconductor layer. This p-type layer is etched to form multiple holes with the etch extending at least into the n-type doped semiconductor layer. In contrast to prior art, shallow etched structures that merely etched the p-type doped semiconductor layer and then applied nano- and micro-particle phosphors thereto, the present invention promotes dipole-dipole nonradiative energy transfer between the quantum dot phosphors and holes. It is appreciated that the relative ordering of n-type and p-type semiconductors are readily inverted to also achieve an operative device.

While the present invention is further detailed with respect to a silicon carbide (SiC) active element, it should be appreciated that other semiconductors are readily substituted in the LEDs detailed herein. Other semiconductors operative herein illustratively include other bimetallic and trimetalic semiconductors based on aluminum nitride and gallium nitride. The hole injection p-type layer includes a silicon carbide (SiC) p-type material, while the electron transport n-type layer includes a SiC n-type material. In at least one embodiment the n-type material is a 2 μm/1×10¹⁶ cm⁻³ n-type epitaxial 4H—SiC layer doped by nitrogen grown on an 8° off-axis n-type 4H—SiC wafer. In at least one embodiment the p-type regions have an area of 1×1 mm2. In at least one embodiment the p-type layer is doped with aluminum ion implantation with the energy/dose of 100 keV/1.5×10¹⁵ cm², followed by an implant anneal process at 1600° C. for 30 minutes.

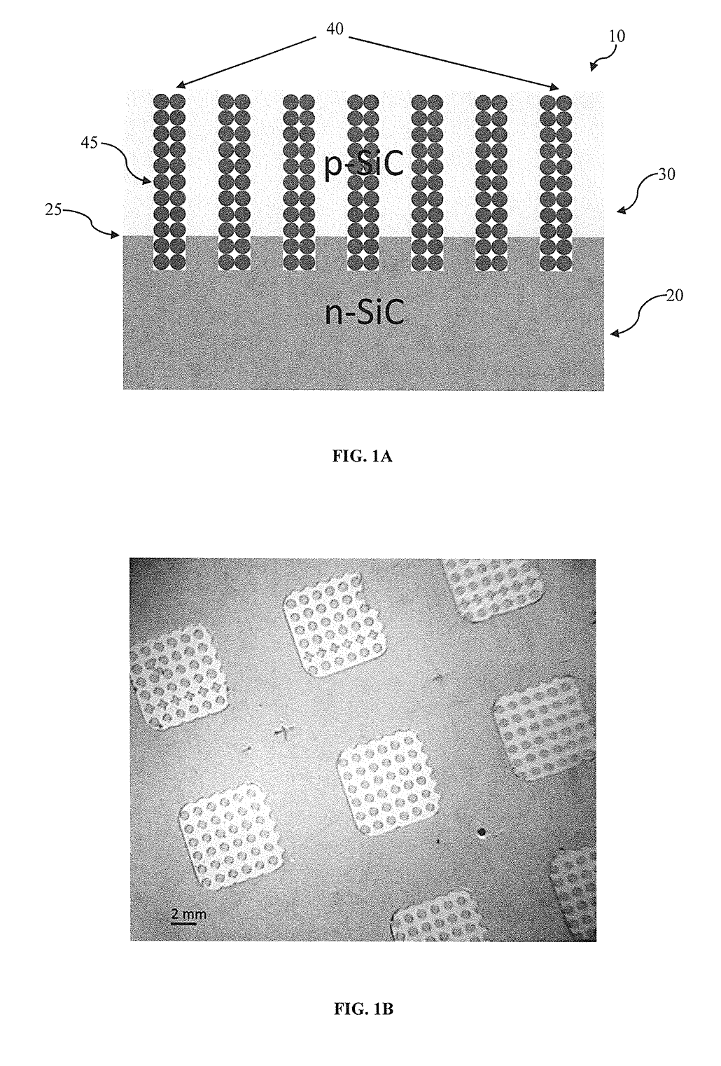

Referring now to FIG. 1 A, a schematic of an inventive LED structure is shown generally at 10. The LED structure 10 has elements built upon a substrate (not illustrated). A substrate operative in the present invention provides mechanical support for the active elements of an LED and is limited only by the requirements that the the LED heterostructure can be lattice-matched or pseudomorphically grown over the substrate material. Substrate materials operative herein include sapphire, quartz, silicon, glass, GaN, zinc oxide (ZnO), and silicon carbide. A representative LED structure 10 at least includes from the bottom up in FIG. 1A, an electron transport n-type layer 20, a hole injection p-type layer 30 directly or indirectly layered on said anode 20 and forming a p-n homojunction 25, and an array of holes 40 etched into at least the p-type layer 30 wherein the etched holes 40 are infiltrated with a plurality of quantum dot phosphors 45. Preferably an inventive LED is based on silicon carbide for the p-type 30 and n-type 20 layers. In some inventive embodiments, the etched holes 40 extend through the p-type layer 30 through the p-n homojunction 25 into the n-type layer 20. The holes 40 formed by the etching process have a mean linear dimension of between 50 nanometers and 1 micron.

The diode further includes an anode and a cathode. In some embodiments the p-type layer 30 is layered directly or indirectly on the anode, the anode is layered directly or indirectly on the p-type layer 30, the n-type layer 20 is layered directly or indirectly on the anode, or the anode is layered directly or indirectly on the n-type layer 20. In some embodiments the n-type layer 20 is layered directly or indirectly on the cathode, the cathode is layered directly or indirectly on the n-type layer 20, the p-type layer 30 is layered directly or indirectly on the cathode, or the cathode is layered directly or indirectly on the p-type layer 30.

In at least one embodiment, the diode includes an anode contact. In at least one embodiment the diode contains a cathode contact. In at least one embodiment the anode contact or the cathode contact are annealed by rapid thermal annealing (RTA) at 1000° C. for 2 minutes to form ohmic contacts. In at least one embodiment the anode contact is an anode contact array with 750 μm hole openings in said p-type region. In at least one embodiment the anode contact arrays are formed using photolithography. In some embodiments a Ti/Al/Ti/Ni (200 Å/400 Å/200 Å/1000 Å) metal stack anode contact is included. The metal stack is deposited by e-beam evaporation and followed by lift-off to form at least one p-type anode contact.

As used herein, an average linear dimension is defined as an average of the maximal linear extent of two orthogonal axes as measured at the top surface of a nanopillar.

It is to be understood that in instances where a range of values are provided that the range is intended to encompass not only the end point values of the range but also intermediate values of the range as explicitly being included within the range and varying by the last significant figure of the range. By way of example, a recited range of from 1 to 4 is intended to include 1-2, 1-3, 2-4, 3-4, and 1-4.

While the formation of holes 40 are right cylinders, with the x-axis and y-axis of approximately equivalent linear extents, it is appreciated that holes 40 may also be conic, triangular, or rectilinear in shape.

In at least one embodiment an intermediate layer is used in simultaneous contact between said anode layer and said substrate. In at least one embodiment a plurality of intermediate layers are provided. In at least one embodiment the intermediate layer is a graphite layer. In at least one embodiment the intermediate layer is a nickel layer. In at least one embodiment the nickel intermediate layer is 1000 Å.

In at least one embodiment a buffer layer may be used to promote the crystal quality of the LED heterostructure. The buffer layer may be of materials known in the art. In one embodiment the buffer layer is In, Al, or GaN.

In some embodiments an insulating layer is used between the p-type material and the n-type material.

Coupling of the quantum dot phosphors to the side walls of the etched holes is employed to achieve efficient non-radiative transfer while retaining the overlying contact electrode structures with dimensions adjustable to desired thicknesses for improved efficiency. In at least one embodiment the quantum dot phosphors are accumulated into the etched holes of the p-type layer by soaking the p-type layer in a toluene solution of quantum dot phosphors for at least 1 hour. In at least one other embodiment, the quantum dot phosphors are accumulated into the etched holes of the p-type layer by soaking said p-type layer in a toluene solution of quantum dot phosphors for at least 12 hours. In at least one embodiment, the etched holes pass through said hole injection layer and into said electron transport layer through the p-n homojunction.

The quantum dot phosphors have a photoluminescence (PL) peak between λ=100 nm and λ=800 nm. In at least one embodiment the quantum dot phosphors have a photoluminescence (PL) peak at λ=610-650 and in other embodiments as 620 nm±5 nm. The quantum dot phosphors are colloidal cadmium selenide (CdSe)/zinc sulfide (ZnS) core/shell quantum dots surface-coated with amine ligands. The band gaps of said plurality of quantum dot phosphors collectively provide an emission discerned by a normal human eye as white in color.

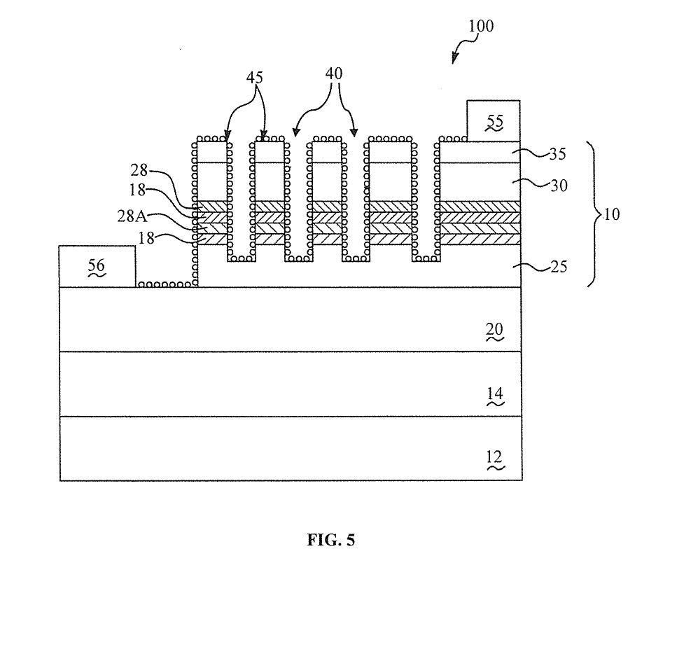

Referring now to FIG. 5, a schematic of at least one embodiment of an inventive LED is shown generally at 100. The LED 100 includes a substrate 12 and the LED structure 10 with a buffer layer 14 deposited intermediate therebetween. On top of the buffer layer, if present in a specific embodiment, is the LED structure shown generally at 10. In some embodiments, the LED 100 further includes one or more quantum wells 18 embedded intrinsically with the LED structure 10. The quantum wells may be formed from any material known in the art. In at least one embodiment the quantum wells are InGaN or GaN. In at least one embodiment the LED structure 10 includes at least one intermediate layer forming a p-i-n structure. In at least one embodiment, where the p-i-n structure is present, the LED structure 10 from the bottom up in FIG. 5 includes, an ohmic contact layer of heavily doped n+ SiC 20, an n-type SiC layer 25, one or multiple quantum wells 18, a p-type SiC layer 30, and an ohmic contact layer of heavily doped p+ SiC cap layer 35. Preferably an inventive LED is based on silicon carbide for the various layers with quantum wells being formed from conventional emissive lattice matched semiconductors of indium gallium nitride (InGaN), aluminum gallium nitride (AlGaN), or aluminum gallium indium nitride (AlGaInN), and combinations thereof. It is appreciated that the relative fractions of aluminum nitride, indium nitride, or a combination thereof within gallium nitride to form a quantum well layer are readily varied as is conventional to the art. Indium gallium nitride quantum wells are known to be adjustable in light emission wavelengths from violet to amber based on composition while aluminum gallium nitride emissions extend from violet into the near ultraviolet of approximately 350 nanometers. It is appreciated that the magnitude of an energy transfer event through a nonradiative transfer mechanism is modified through selection of quantum well composition.

Upon forming a multilayer stack of layers 20-25-18-30-35 on substrate 12 with optional intermediate layers 28, and 28A, the stack is etched to form an array of etched holes 40 with the etched holes 40 extending at least into contact with the quantum well layer 18. The intermediate layers 28 and 28A are in some embodiments intrinsic semiconductors such as SiC or GaN that clad the quantum well layer and have a band gap greater than the quantum well. In some inventive embodiments, the etched holes 40 extend through the entire stack of the LED structure 10.

The etched holes 40 are then infiltrated with quantum dot phosphors 45. Those quantum dot phosphors proximal to the quantum wells 18 exposed along side walls of the etched holes 40 are now capable of being emissively stimulated through a nonradiative energy transfer from the quantum well 18 to the quantum dot phosphors 45. The quantum dot phosphors 45 along the sidewalls of the etched holes 40 emit with an efficiency superior to that of conventional LEDs. An inventive LED 100 is completed through inclusion of an anode 55 in electrical contact with p type layer 35 and a cathode 56 in electrical contact with heavily doped n+ GaN 20. Forming an electrical circuit between the anode 55 and cathode 56 with a power source having a voltage to induce spectral emission from said at least one quantum well 18 produces emission from the quantum dot phosphors through non-radiative coupling to the quantum wells 18.

### EXAMPLE 1

### Fabrication of Silicon Carbide Quantum Dot Phosphor LED's

A silicon carbide (SiC) p-n junction was fabricated and surface-patterned with arrays of holes, facilitating sidewall-coupling between the QDs and the SiC p-n junction. Nonradiative energy transfer was observed from the SiC diode to colloidal QD-phosphors that accumulated in the holes. Enhanced red emission of QDs was measured from characterization of the electroluminescence spectra of the diode, with a color conversion quantum efficiency calculated to be 3.1%. Time resolved photoluminescence (TRPL) was also performed, and the photoluminescence (PL) decay lifetime of the SiC junction was found to decrease from 24.1 ns to 21.7 ns following the QD deposition, further confirming the existence of the nonradiative energy transfer path between the QDs and the SiC diode.

A SiC diode is fabricated with arrays of holes that are infiltrated with QD phosphors. The QD phosphors are colloidal CdSe/ZnS core/shell QDs (QSP-620, Ocean Nanotech LLC) that are surface-coated with amine ligands. The nanoparticles exhibit a photoluminescence (PL) peak at λ=620 nm, and are accumulated into the holes of the SiC diode by soaking the devices in a toluene solution of QDs for 12 hours. Each hole is configured to trench through the p-n homojunction, with a 2 μm/1×10¹⁶ cm⁻³ n-type epitaxial 4H—SiC layer doped by nitrogen grown on an 8° off-axis n-type 4H—SiC wafer. FIG. 1A schematically represents the fabricated diode.

The p-type regions, with an area of 1×1 mm², are formed by aluminum ion implantation with the energy/dose of 100 keV/1.5×10¹⁵ cm⁻², followed by an implant anneal process at 1600° C. for 30 minutes. To avoid Si outgassing from the sample during annealing, a graphite layer is used to protect the surface of the diode during the implant anneal. A 50-5000 Å Ni layer is deposited on the backside of the diode by e-beam evaporation to form the n-type cathode contact. Photolithography is then used to pattern the anode contact arrays with 750 μm hole openings in the p-type front side of the diode, as illustrated in the photomicrograph (FIG. 1B).

Finally, a Ti/Al/Ti/Ni metal stack (20-2000 Å/40-4000 Å/20-2000 Å/100-5000 Å), and in specific embodiments nominally: (200 Å/400 Å/200 Å/1000 Å) is deposited by e-beam evaporation and followed by lift-off to form the p-type anode contacts. Both anode and cathode contacts are annealed by rapid thermal annealing (RTA) at 1000° C. for 2 minutes to form ohmic contacts. The holes on the anode contacts have a nominal depth of 0.5 μm, which are etched through the p-type SiC layer and into the n-type SiC layer by reactive ion etching (RIE) using SF₆ process gas.

### EXAMPLE 2

### Characterization of Silicon Carbide Quantum Dot Phosphor LED's

For device characterization, electrical pumping is implemented by forward-biasing the SiC p-n junction with a Keithley 2612B semiconductor parameter analyzer. The electroluminescent emission of the diode is characterized with an integrating sphere-measurement for full collection of the non-Lambertian radiation pattern. The diode is placed inside the integrating sphere (Thorlabs MA189), where the output emission of the diode is diffusely reflected by the barium sulfate-coated inner surface of the sphere and redistributed isotropically into all solid angles; the spectral and intensity detection of the light exiting from a small aperture at the sphere surface facilitates an accurate determination of the total number of photons from the nano-structured emitter. The output of the integrating sphere is coupled, via an optical fiber, to a spectrometer (Spectropro, ˜0.1 nm spectral-resolution) equipped with a p-i-n photodetector. Both the dispersion of the spectrometer grating and the response of the photodetector are calibrated to ensure detection linearity. A barium sulfate-coated baffle is placed in front of the fiber coupler at the interior surface of the integration sphere to prevent direct illumination of the optical fiber during optical pumping.

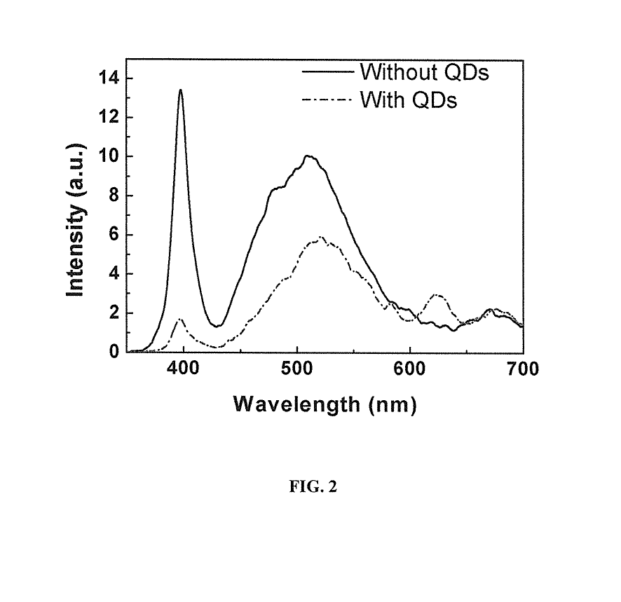

The diode is forward-biased with a 90 mA pulse-current at the repetition rate of 1000 Hz and 50% duty cycle. The output electroluminescence (EL) spectra of a SiC diode prior to and after QD infiltration are plotted in FIG. 2. Since SiC is an indirect band-gap semiconductor, the EL emission of the diode is weak and comprised of two primary spectral features: a near ultra violet (UV) band and a green band. The near UV emission is intrinsically narrow and arises from carrier relaxation via the indirect band-gap of SiC, while the broader green band is due to defect states of the material. After the QD infiltration, the red emission is observed resulting from the coupling between QDs and SiC. The color conversion (quantum) efficiency (η_{c}), defined as the ratio of the photon counts from SiC-QD coupled device (N_{QD}^{SiC⇄QD}) to that from the net SiC emission (N^{SiC}), N_{QD}^{SiC⇄QD}/N^{SiC}, is calculated to be 3.1% from FIG. 2, by calculating the ratio of the area of red QD emission to that of the blue-green emission of the pristine SiC diode prior to QD deposition.

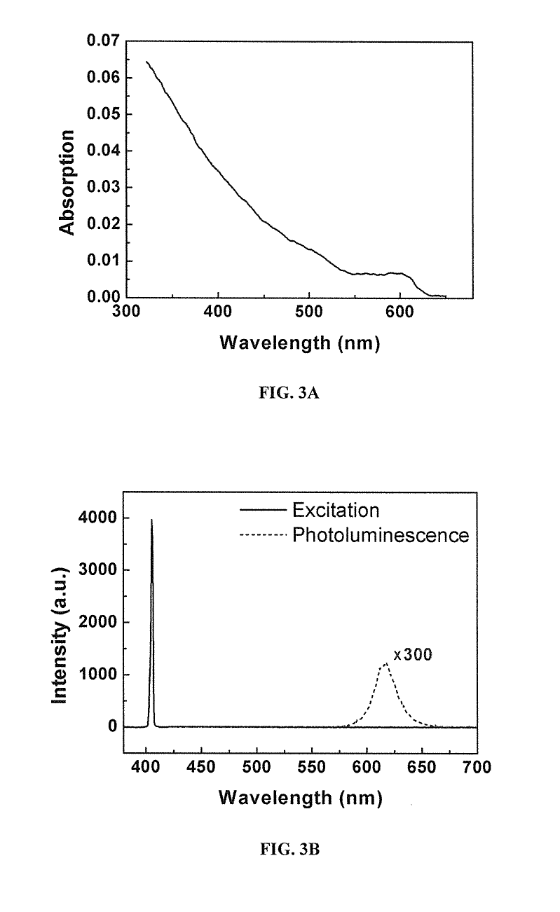

In order to accurately assess the fraction of the color conversion efficiency due to the nonradiative energy transfer process, it is necessary to exclude the contribution to the observed QD emission via the traditional absorption/re-emission path. A control sample of QD film is obtained on a UV-ozone cleaned glass substrate via the same soaking processes that used in the aforementioned QD deposition on SiC sample. The absorption spectrum of the QD film is recorded using a Perkin-Elmer Lambda 19 UV/visible/near infrared spectrometer, as shown in FIG. 3A. The mean absorbance of the SiC emission by the QD film is calculated by integrating spectra of the QD absorption and the EL emission of SiC diode, yielding a value of 0.017. Next, the integration sphere technique is used to determine the quantum yield of the QD film, using a pump source of 405 nm diode laser. The spectra of the excitation and PL of the thin film is presented in FIG. 3B, and the measured quantum yield is ˜36.9%. Given the fact that the quantum yield of QDs varies little with the excitation wavelength, the conversion efficiency of the traditional absorption/re-emission path is consequently calculated as the product of the mean absorbance (0.017) and the QD quantum yield (36.9%) of the QD film, resulting in an efficiency of ˜0.63%. As such, the quantum efficiency of the QD emission via the nonradiative energy transfer path is determined as 3.1%-0.63%=2.47%. Thus the pronounced attenuation in the EL intensity following the QD incorporation into the SiC diode is not induced by the traditional absorption/re-emission of the QD film, but instead by the non-radiative energy transfer between QDs and SiC diode.

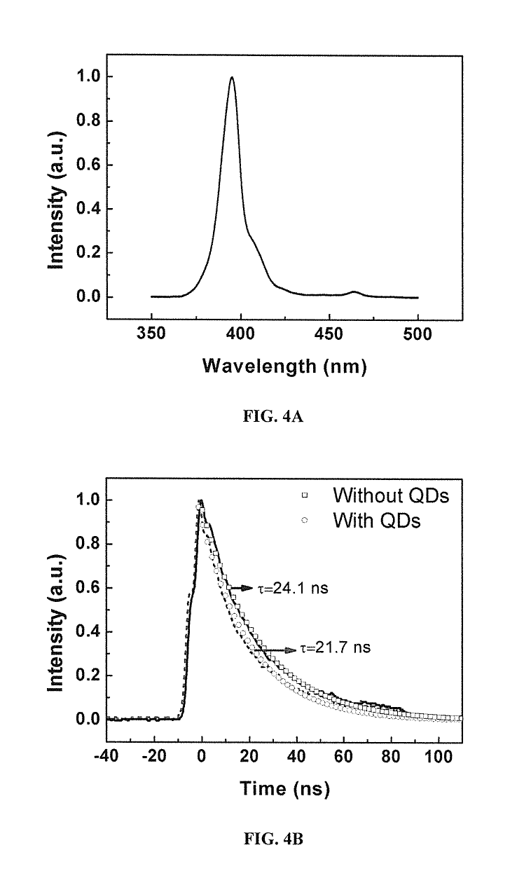

Finally, TRPL measurements are conducted to determine the rate of nonradiative energy transfer between QDs and the SiC p-n junction. The third harmonic (λ=267 nm) of a Ti:sapphire femtosecond amplifier (800 nm, 1 kHz, 80 fs, Coherent Libra system) is introduced into the integrating sphere to excite the sample optically. The PL spectrum of the SiC material exhibits a peak at ˜392 nm, which matches well with the indirect band-gap energy (˜3.2 eV) of SiC (FIG. 4A). By resolving the temporal decay of the indirect band-gap emission of the SiC diode with and without QD phosphor coating, the carrier relaxation process in the p-n junction is revealed, as plotted in FIG. 4B. A recombination lifetime of ˜24.1 ns is measured in the diode without the QD phosphors, whereas the lifetime dropped to 21.7 ns after QD phosphor deposition, indicating that the carriers in the SiC diode relax faster in the presence of QDs. Since the deposition of QDs does not change the intrinsic carrier dynamics of the SiC diode, this faster decay suggests that an additional relaxation channel is introduced, which can only be the nonradiative energy transfer from SiC to QDs. The energy transfer rate is readily determined as 1/21.7-1/24.1=4.59 μs⁻¹. Although this rate is approximately two or three orders of magnitude lower than the radiative recombination rate of some direct band-gap semiconductors, such as InGaN or GaAs, nonradiative energy transfer is demonstrated as an effective path to achieve color tunable emission from indirect band gap semiconductors.

### REFERENCES

Marc Achermann, Melissa A. Petruska, Simon Kos, Darryl L. Smith, Daniel D. Koleske and Victor I. Klimov, “Energy-transfer pumping of semiconductor nanocrystals using an epitaxial quantum well”, Nature, 429, 642-646 (2004).

Hsueh-Shih Chen, Cheng-Kuo Hsu, and Hsin-Yen Hong, “InGaN—CdSe—ZnSe Quantum Dots White LEDs” IEEE Photon Tech. Lett. 18 (1) 193-195 (2006).

Marc Achermann, Melissa A. Petruska, Daniel D. Koleske, Mary H. Crawford, and Victor I. Klimov, “Nanocrystal-Based Light-Emitting Diodes Utilizing High-Efficiency Nonradiative Energy Transfer for Color Conversion”, Nano Lett., 6, 1396-1400 (2006).

V. L. Colvin, M. C. Schlamp and A. P. Alivisatos, Nature 370 (1994), no. 6488, 354-357.

S. Coe, W.-K. Woo, M. Bawendi and V. Bulovic, Nature 420 (2002), no. 6917, 800-803.

Q. Sun, Y. A. Wang, L. S. Li, D. Y. Wang, T. Zhu, J. Xu, C. H. Yang and Y. F. Li, Nat Photonics 1 (2007), no. 12, 717-722.

Z. Tan, F. Zhang, T. Zhu, J. Xu, A. Y. Wang, J. D. Dixon, L. Li, Q. Zhang, S. E. Mohney and J. Ruzyllo, Nano Lett 7 (2007), no. 12, 3803-3807.

S. Nizamoglu, G. Zengin and H. V. Demir, Applied Physics Letters 92 (2008), no. 3, 031102.

E. Jang, S. Jun, H. Jang, J. Lim, B. Kim and Y. Kim, Adv Mater 22 (2010), no. 28, 3076-3080.

S. Chanyawadee, P. G. Lagoudakis, R. T. Harley, M. D. B. Charlton, D. V. Talapin, H. W. Huang and C. H. Lin, Adv Mater 22 (2010), no. 5, 602-606.

F. Zhang, J. Liu, G. You, C. Zhang, S. E. Mohney, M. J. Park, J. S. Kwak, Y. Wang, D. D. Koleske and J. Xu, Opt. Express 20 (2012), no. S2, A333-A339.

M. Ikeda, H. Matsunami and T. Tanaka, Jpn J Appl Phys 19 (1980), no. 6, 1201-1202.

C.-K. Sun, S. Keller, G. Wang, M. S. Minsky, J. E. Bowers and S. P. DenBaars, Applied Physics Letters 69 (1996), no. 13, 1936-1938.

Patent documents and publications mentioned in the specification are indicative of the levels of those skilled in the art to which the invention pertains. These documents and publications are incorporated herein by reference to the same extent as if each individual document or publication was specifically and individually incorporated herein by reference.

The foregoing description is illustrative of particular embodiments of the invention, but is not meant to be a limitation upon the practice thereof. The following claims, including all equivalents thereof, are intended to define the scope of the invention.

1. A light emitting diode comprising:
a substrate;
a cathode having at least one cathode contact, said cathode directly or indirectly layered on said substrate;
an electron transport layer comprising of a SiC n-type material directly or indirectly layered on said cathode;
a hole injection layer comprising of a silicon carbide (SiC) p-type material directly or indirectly layered on said electron transport layer forming a p-n homojunction therebetween;
an array of holes etched in said p-type layer;
a plurality of quantum dot phosphors, wherein said array of holes etched in the p-type layer are infiltrated with said plurality of quantum dot phosphors;
an anode having at least one anode contact, said anode directly or indirectly layered on said substrate; and
a hole injection layer comprising of a silicon carbide (SiC) p-type material directly or indirectly layered on said hole injection layer.

2. The diode of claim 1 wherein said quantum dot phosphors are colloidal cadmium selenide (CdSe)/zinc sulfide (ZnS) core/shell quantum dots surface-coated with amine ligands.

3. The diode of claim 1 wherein said quantum dot phosphors have a photoluminescence (PL) peak at λ=620 nm±5 nm.

4. The diode of claim 1 wherein said quantum dot phosphors are accumulated into the etched holes of said p-type layer by soaking said p-type layer in a solution of quantum dot phosphors.

5. The diode of claim 1 wherein said quantum dot phosphors are accumulated into the etched holes of said p-type layer by soaking said p-type layer in a solution of quantum dot phosphors for at least 12 hours.

6. The diode of claim 1 wherein said etched holes pass through said hole injection layer and into said electron transport layer through the p-n homojunction.

7. The diode of claim 1 wherein said n-type material is a n-type epitaxial 4H—SiC layer doped by nitrogen.

8. The diode of claim 1 wherein the p-type regions have an area of at least 1 mm².

9. The diode of claim 1 wherein the p-type layer is doped with aluminum ion implantation.

10. The diode of claim 1 further comprising an intermediate layer in simultaneous contact between said anode layer and said substrate.

11. The diode of claim 9 wherein said intermediate layer is a graphite layer.

12. The diode of claim 9 wherein said intermediate layer is a nickel layer.

13. The diode of claim 11 wherein the nickel layer is 100-5000 Å.

14. The diode of claim 1 wherein said anode contact and cathode contact are annealed by rapid thermal annealing (RTA) to form ohmic contacts.

15. The diode of claim 1 wherein said anode contact is an anode contact array with 750 μm hole openings in said p-type region.

16. The diode of claim 14 wherein said anode contact arrays are formed using photolithography.

17. The diode of claim 1 further comprising a Ti/Al/Ti/Ni metal stack anode contact.

18. The diode of claim 16 wherein the metal stack is deposited by e-beam evaporation.

19. The diode of claim 1 wherein the band gaps of said plurality of quantum dot phosphors collectively provide an emission discerned by a normal unaided human eye as white in color.

20. The diode of claim 1 further comprising at least one buffer layer between the substrate and the n-type layer.

21. The diode of claim 1 further comprising at least one quantum well layer.
